(19) United States
(12) Patent Application Publication
(10) Pub. No.: US 2018/0047576 A1
(43) Pub. Date: Feb. 15, 2018

(54) SUBSTRATE PROCESSING DEVICE AND SUBSTRATE PROCESSING METHOD

(71) Applicant: SCREEN Holdings Co., Ltd., Kyoto (JP)

(72) Inventors: Hiroaki TAKAHASHI, Kyoto (JP); Masayuki OTSUJI, Kyoto (JP)

(21) Appl. No.: 15/557,146

(22) PCT Filed: Feb. 29, 2016
(86) PCT No.: PCT/JP2016/056039

§ 371 Date: Sep. 11, 2017

(30) Foreign Application Priority Data
Mar. 26, 2015 (JP) 2015-064945

(51) Int. Cl. H01L 21/306; H01L 21/67; H01L 21/683

(52) U.S. Cl. CPC H01L 21/30604; H01L 21/6833; H01L 21/6708

(57) ABSTRACT

A substrate processing device includes a control device that controls a substrate holding unit, an etching liquid supply unit, and a plurality of electrodes. The control device performs an etching step for supplying an etching liquid to a substrate, while rotating the substrate about a rotation axis line; and in parallel with the etching step, an etching electrostatically charging step for electrostatically charging the substrate by applying voltages to the electrodes such that the absolute value of the voltage to be applied to the first electrode and the absolute value of the voltage to be applied to the second electrode are increased in this order.

### TECHNICAL FIELD

The present invention relates to a substrate processing apparatus and a substrate processing method which process a substrate. Substrates to be processed include, for example, semiconductor wafers, liquid crystal display device substrates, plasma display substrates, FED (Field Emission Display) substrates, optical disk substrates, magnetic disk substrates, magneto-optical disk substrates, photomask substrates, ceramic substrates, and photovoltaic cell substrates.

### BACKGROUND ART

PATENT DOCUMENT 1 discloses a single substrate processing type substrate processing apparatus that processes a substrate one by one. With this substrate processing apparatus, to suppress or prevent a substrate from becoming oxidized in a resist removing processing or a rinse processing, a processing liquid, such as SPM (a mixed liquid containing sulfuric acid and hydrogen peroxide water), etc., is supplied to a front surface of the substrate in a state where an entirety of the substrate is electrostatically charged negatively substantially uniformly.

### PRIOR ART DOCUMENT

### Patent Document

PATENT DOCUMENT 1: JP 2009-238862 A

### SUMMARY OF THE INVENTION

### Problem(s) to be Solved by the Invention

In a manufacturing process for a semiconductor device or a liquid crystal display device, etc., an etching step of etching a substrate, such as a semiconductor wafer, a glass substrate for liquid crystal display device, etc., is performed. In PATENT DOCUMENT 1, although suppression or prevention of oxidation of the substrate by making use of electrostatic charging of the substrate is disclosed, no disclosure is made in regard to etching of the substrate.

Therefore, an object of the present invention is to make use of electrostatic charging of the substrate to increase uniformity of etching.

### Means for Solving the Problem

A preferred embodiment of the present invention provides a substrate processing apparatus including a substrate holding unit, rotating a substrate around a rotational axis passing through a central portion of the substrate while holding the substrate, an etching liquid supplying unit, supplying an etching liquid to a major surface of the substrate held by the substrate holding unit, a plurality of electrodes, including a first electrode, facing the substrate held by the substrate holding unit, and a second electrode, disposed at a position more distant than that of the first electrode from the rotational axis and facing the substrate held by the substrate holding unit, and a controller, controlling the substrate holding unit, the etching liquid supplying unit, and the plurality of electrodes.

The controller is programmed to execute an etching step of supplying the etching liquid to the major surface of the substrate while rotating the substrate around the rotational axis, and an etching electrostatic charging step of applying voltages to the plurality of electrodes such that absolute values of the applied voltages increase in the order of the first electrode and the second electrode to electrostatically charge the major surface of the substrate in parallel to the etching step. The “major surface of the substrate” signifies a front surface, which is a device forming surface, or a rear surface opposite the front surface.

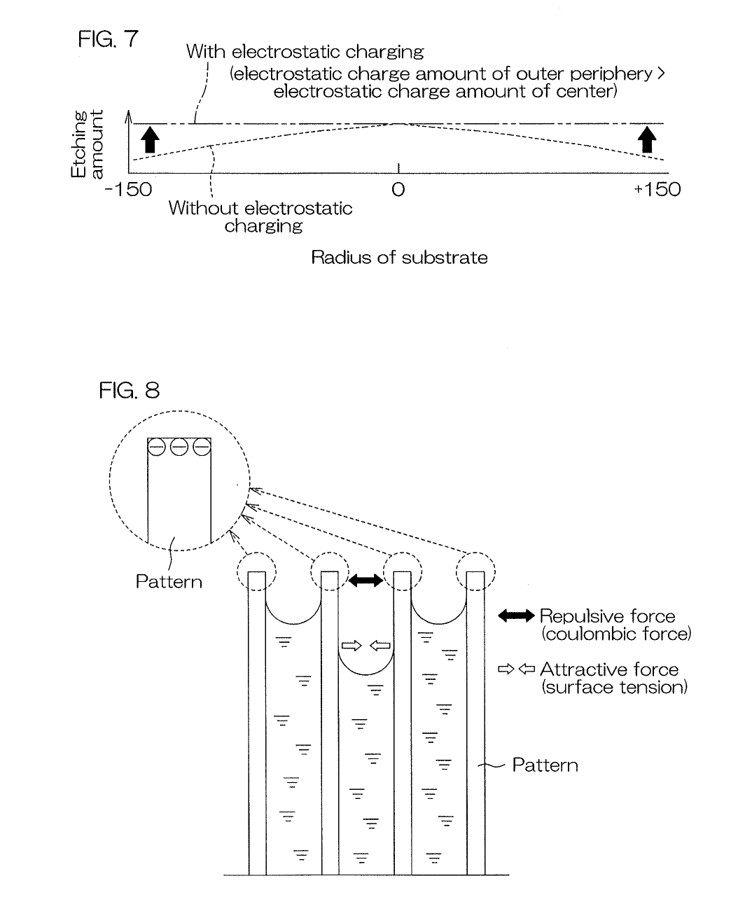

When the etching liquid is supplied to an upper surface central portion of the substrate while rotating the substrate within a horizontal plane, a substrate etching amount becomes greatest at the upper surface central portion of the substrate and decreases with separation from the upper surface central portion of the substrate (see broken line in FIG. 7). Although the uniformity of etching is increased when a liquid landing position of the etching liquid with respect to the upper surface of the substrate is moved between the central portion and a peripheral edge portion, such a hill-shaped distribution still appears.

The present inventors found that when a major surface (front surface or rear surface) of the substrate is electrostatically charged either positively or negatively, an etching amount per unit time (etching rate) increases. It was further found that the etching rate increases as an electrostatic charge amount of the major surface of the substrate increases. The uniformity of etching can thus be increased by electrostatically charging the major surface of the substrate such that the electrostatic charge amount increases continuously or stepwise with separation from the major surface central portion of the substrate (see alternate long and two short dashed line in FIG. 7).

With the substrate processing apparatus according to the present preferred embodiment, the substrate is electrostatically charged by applying voltages to the plurality of electrodes. The etching liquid is supplied to the major surface of the substrate while rotating the substrate around the rotational axis passing through the central portion of the substrate in a state where the substrate is electrostatically charged. The major surface of the substrate is thereby etched.

The plurality of electrodes include the first electrode and the second electrode that face the substrate. A distance in a radial direction (direction orthogonal to the rotational axis) from the rotational axis of the substrate to the first electrode is less than a distance in the radial direction from the rotational axis of the substrate to the second electrode. That is, the second electrode faces the substrate at a position further outward than the first electrode.

The absolute value of the voltage applied to the second electrode is greater than the absolute value of the voltage applied to the first electrode. The major surface of the substrate is thus electrostatically charged such that the electrostatic charge amount increases stepwise with separation from the major surface central portion of the substrate. The uniformity of etching can thus be increased in comparison to a case where the major surface of the substrate is etched in a state where the substrate is electrostatically charged uniformly.

The controller may further execute a condition checking step of checking a processing condition of the substrate in the etching step and a voltage determining step of determining, based on the processing condition, the absolute values of the voltages applied to the plurality of electrodes in the etching electrostatic charging step. “Processing conditions of the substrate” include, for example, at least one among etching liquid type, etching liquid flow rate, etching liquid temperature, etching liquid concentration, etching liquid supplying time, and rotational speed of a substrate during etching liquid supplying.

When the upper surface of the substrate is etched without electrostatically charging the substrate, the etching amount of the substrate ordinarily exhibits a hill-shaped distribution regardless of the processing conditions of the substrate, including the etching liquid type, etching liquid flow rate, etching liquid temperature, etching liquid concentration, etching liquid supplying time, and rotational speed of substrate during etching liquid supplying. However, there are cases where a slope of the hill-shaped curve changes when at least one of the processing conditions differs. With the present arrangement, the absolute values of the voltages applied to the plurality of electrodes are determined based on the processing conditions and the voltages of the determined magnitudes are applied to the plurality of electrodes. The uniformity of etching can thus be increased in comparison to a case where the absolute values of the applied voltages remain the same regardless of the processing conditions of the substrate.

The etching electrostatic charging step may be a step of applying voltages to the plurality of electrodes such that the major surface of the substrate becomes electrostatically charged positively when the etching liquid is acidic and applying voltages to the plurality of electrodes such that the major surface of the substrate becomes electrostatically charged negatively when the etching liquid is alkaline.

When an alkaline liquid is supplied to the major surface of the substrate, particles in the liquid become electrostatically charged negatively. When an acidic liquid is supplied to the major surface of the substrate, particles in the liquid become electrostatically charged positively, depending on the pH. When an acidic etching liquid is supplied to the substrate, the controller makes the major surface of the substrate become electrostatically charged positively. Oppositely, when an alkaline etching liquid is supplied to the substrate, the controller makes the major surface of the substrate become electrostatically charged negatively. That is, the controller controls a polarity of the voltages applied to the respective electrodes such that electrical repulsive forces act between the particles and the major surface of the substrate. The particles can thereby be removed from the major surface of the substrate and reattachment of the particles can be suppressed or prevented.

The substrate may be a substrate at the major surface of which a pattern is exposed. The controller may further execute a drying step of removing liquid from the substrate to dry the substrate after the etching step and a drying electrostatic charging step of applying voltages to the plurality of electrodes to electrostatically charge the major surface of the substrate in parallel to the drying step. The voltages applied to the respective electrodes in the drying electrostatic charging step may be equal or may differ in magnitude.

With the present arrangement, the liquid is removed from the substrate in the state where the substrate is charged. The substrate is thereby dried.

When a substrate having patterns formed thereon is electrostatically charged, an electrical bias arises in the patterns. Therefore, as shown in FIG. 8, electric charges of the same polarity gather at tips of the respective patterns and the tips of the respective patterns become electrostatically charged with the same or substantially the same amount of electrostatic charge of the same polarity. A repulsive force (coulombic force) thus acts on two adjacent patterns.

On the other hand, when a liquid surface is present between two adjacent patterns, a surface tension of the liquid acts at boundary positions between the liquid surface and the patterns. That is, an attractive force (surface tension) acts on the two adjacent patterns. However, this attractive force (surface tension) is offset by the repulsive force (coulombic force) due to the electrostatic charging of the substrate. The substrate can thus be dried while reducing forces that act on the patterns. Occurrence of pattern collapse can thereby be lessened.

The plurality of electrodes may face the major surface of the substrate.

With the present arrangement, the plurality of electrodes are disposed at the side of the major surface (one of the major surfaces) of the substrate and face tips of patterns formed on the major surface of the substrate. Distances from the plurality of electrodes to the tips of patterns can thus be reduced in comparison to a case where the plurality of electrodes are disposed at the side of the other major surface (the surface opposite the one major surface) of the substrate and the occurrence of pattern collapse can be lessened.

The substrate processing apparatus may further include a dielectric body, in which the plurality of electrodes are embedded and which is interposed between the substrate held by the substrate holding unit and the plurality of electrodes.

With the present arrangement, the plurality of electrodes face the substrate via the dielectric body. Due to the dielectric body, made of insulating material, being present between the substrate and the plurality of electrodes, electric charges do not or are unlikely to move between the substrate and the plurality of electrodes via the dielectric body. The substrate can thus be reliably maintained in the electrostatically charged state and the electrostatic charge amount of the substrate can be stabilized. The uniformity of etching can thereby be increased more reliably.

A distance from the substrate, held by the substrate holding unit, and the plurality of electrodes may be less than a thickness of the dielectric body.

The “distance from the substrate to the plurality of electrodes” signifies the shortest distance from the substrate to the plurality of electrodes in an orthogonal direction orthogonal to the major surface of the substrate. If the substrate is held horizontally, the orthogonal direction signifies a vertical direction. The “thickness of the dielectric body” signifies the minimum value of length of the dielectric body in the orthogonal direction at a position of passing through any of the plurality of electrodes. If the dielectric body has the shape of a plate that is held horizontally, the thickness of the dielectric body signifies a distance in the vertical direction from an upper surface of the dielectric body to a lower surface of the dielectric body.

With the present arrangement, the plurality of electrodes are disposed close to the substrate such that the distance from the substrate to the plurality of electrodes is less than the thickness of the dielectric body. If the distance from the substrate to the plurality of electrodes is large, high voltages must be applied to the plurality of electrodes to electrostatically charge the substrate. Therefore, by disposing the plurality of electrodes close to the substrate, the substrate can be electrostatically charged reliably while suppressing the absolute values of the applied voltages.

At least one of the plurality of electrodes may be an annular electrode that surrounds the rotational axis. In this case, the annular electrode may be of a C-shape that surrounds the rotational axis or an O-shape that surrounds the rotational axis. Preferably, a distance in the radial direction from the rotational axis to the annular electrode is constant at all positions in a peripheral direction (direction around the rotational axis). When at least one of the plurality of electrodes is the annular electrode, variation of the electrostatic charge amount of the substrate in the peripheral direction can be reduced. The uniformity of etching can thereby be increased.

Another preferred embodiment of the present invention provides a substrate processing method including an etching step of supplying an etching liquid to a major surface of a substrate while rotating the substrate around a rotational axis passing through a central portion of the substrate, and an etching electrostatic charging step of electrostatically charging the major surface of the substrate in parallel to the etching step such that an electrostatic charge amount increases as a distance from a central portion of the major surface of the substrate increases.

The substrate processing method may further include a condition checking step of checking, in the etching step, a processing condition of the substrate that includes a type of the etching liquid supplied to the major surface of the substrate. The etching electrostatic charging step may be a step of electrostatically charging the major surface of the substrate positively if the etching liquid is acidic and electrostatically charging the major surface of the substrate negatively if the etching liquid is alkaline.

The substrate may be a substrate at the major surface of which a pattern is exposed. The substrate processing method may further include a drying step of removing liquid from the substrate to dry the substrate after the etching step and a drying electrostatic charging step of electrostatically charging the major surface of the substrate in parallel to the drying step.

The above and other objects, features, and effects of the present invention will become more apparent from the following detailed description of the preferred embodiments with reference to the attached drawings.

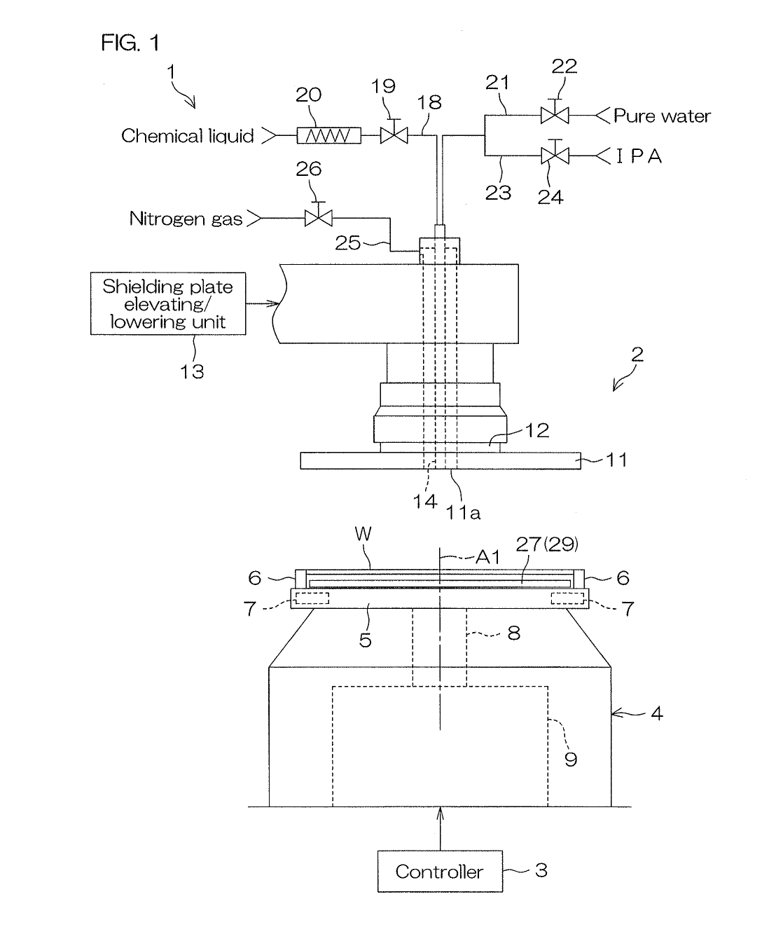

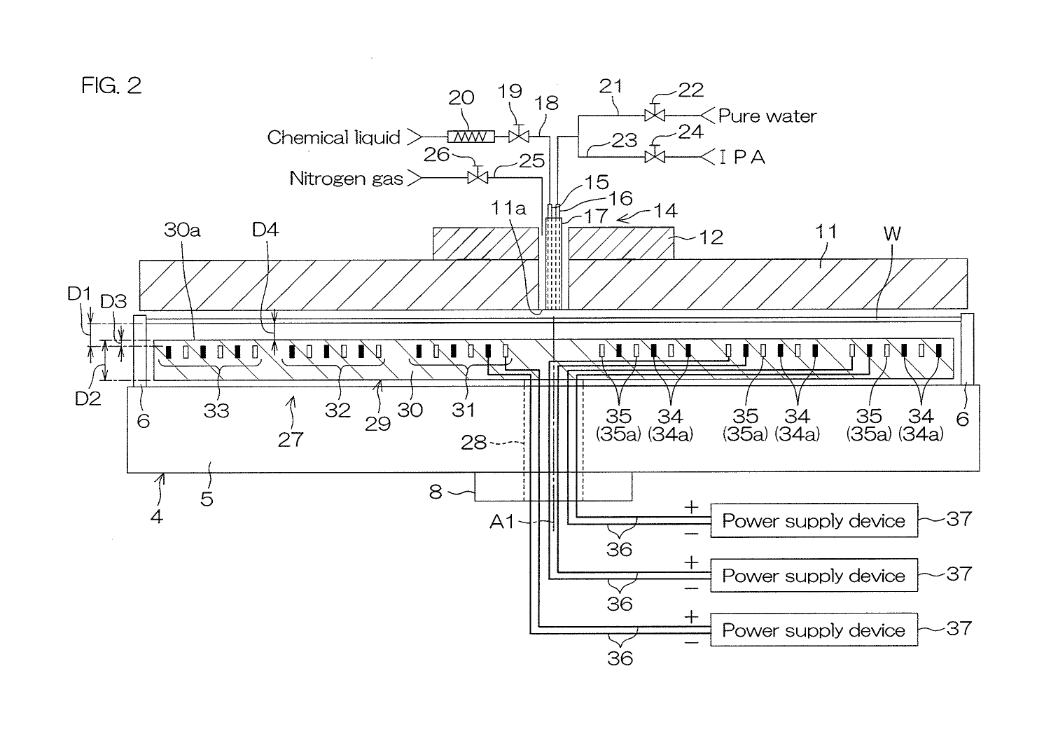

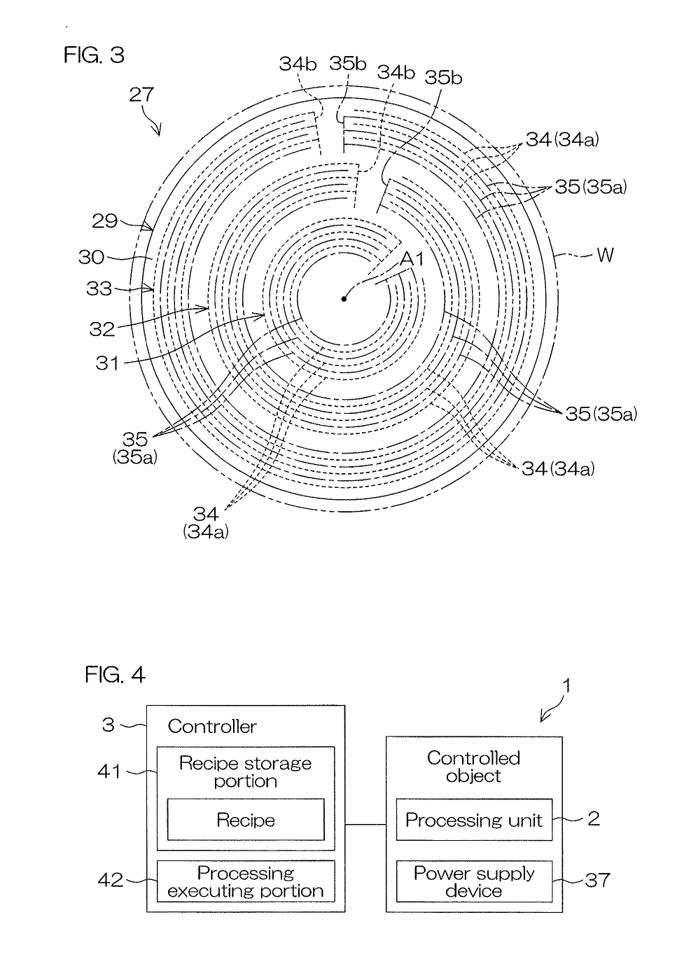

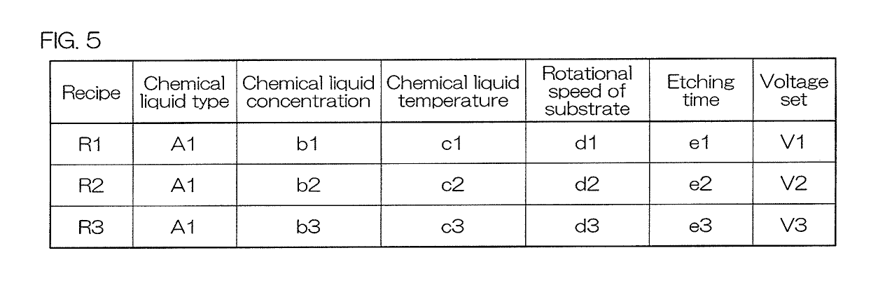

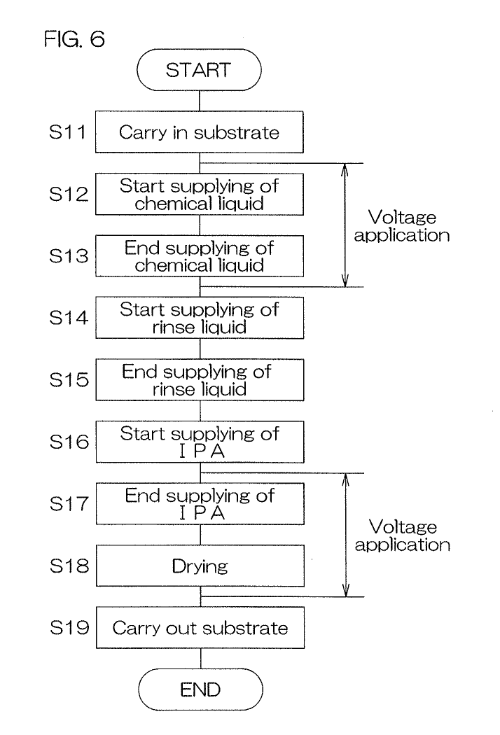

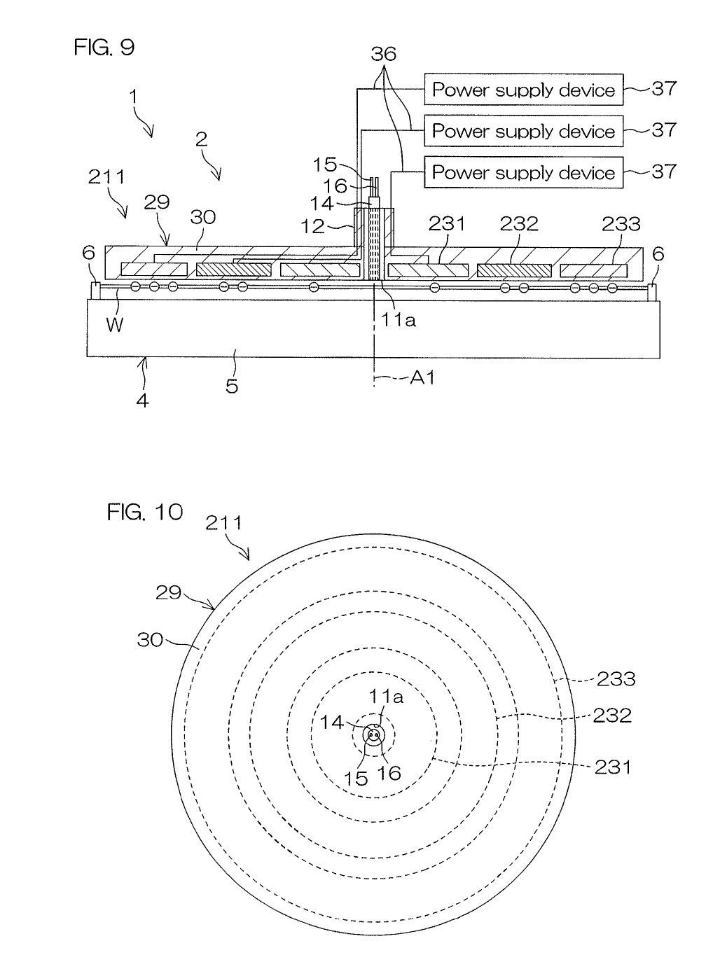

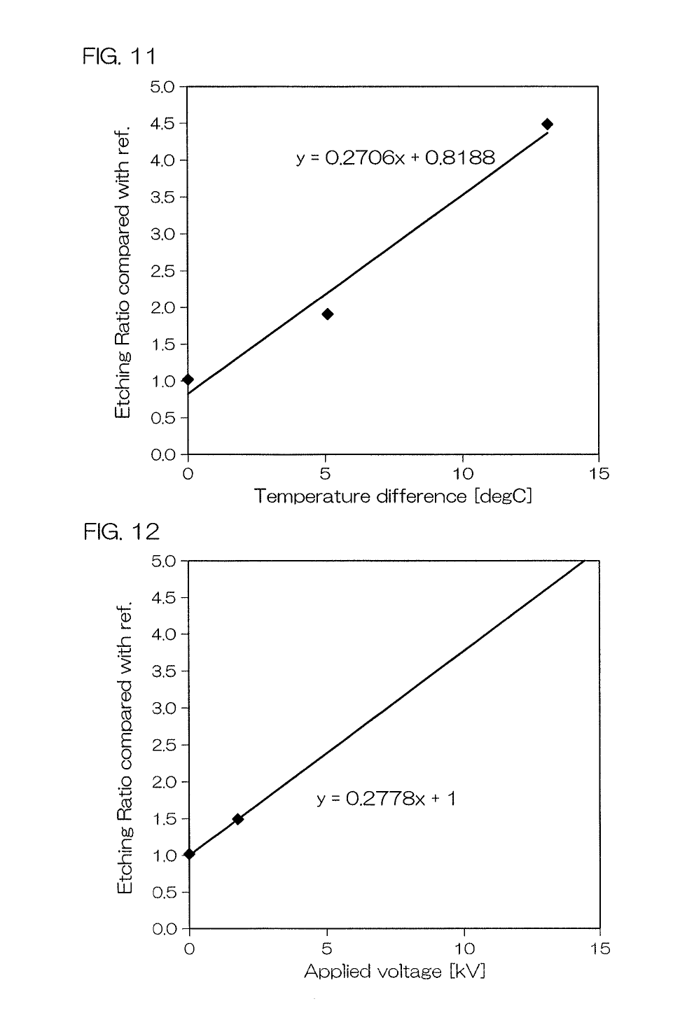

### BRIEF DESCRIPTION OF THE DRAWINGS

[FIG. 1] a schematic view of the interior of a processing unit included in a substrate processing apparatus according to a first preferred embodiment of the present invention when viewed horizontally.

[FIG. 2] a sectional view of a vertical section of a facing member included in the processing unit.

[FIG. 3] a plan view of the facing member showing a configuration of a plurality of electrodes embedded in the facing member.

[FIG. 4] a block diagram showing the electrical construction of the substrate processing apparatus.

[FIG. 5] a table indicating contents of a recipe stored in a storage device of a controller.

[FIG. 6] a flowchart for describing an example of processing of a substrate executed by the substrate processing apparatus.

[FIG. 7] a graph showing a conceptual image of a distribution of etching amount when an upper surface of a substrate is etched without electrostatically charging the substrate (broken line) and a conceptual image of a distribution of etching amount when the respective steps shown in FIG. 6 are executed (alternate long and two short dashed line).

[FIG. 8] a schematic diagram for describing forces that act on patterns when a substrate is dried.

[FIG. 9] a sectional view of a vertical section of a facing member according to a second preferred embodiment of the present invention.

[FIG. 10] a bottom view of a shielding plate (facing member) showing a configuration of a plurality of electrodes embedded in the facing member.

[FIG. 11] a graph of correlation of chemical liquid temperature and etching rate. The abscissa indicates a difference between a reference temperature and the chemical liquid temperature and the ordinate indicates an etching rate multiplication factor with respect to the etching rate at the reference temperature.

[FIG. 12] a graph of correlation of applied voltage and etching rate. The abscissa indicates a difference between a reference voltage and the applied voltage and the ordinate indicates an etching rate multiplication factor with respect to the etching rate at the reference voltage.

### DESCRIPTION OF PREFERRED EMBODIMENTS

FIG. 1 is a schematic view of the interior of a processing unit 2 included in a substrate processing apparatus 1 according to a first preferred embodiment of the present invention when viewed horizontally.

The substrate processing apparatus 1 is a single substrate processing type apparatus that processes disk-shaped substrates W, such as semiconductor wafers, etc., one at a time. The substrate processing apparatus 1 includes a processing unit 2 that processes the substrate W using a processing liquid, a transfer robot (not shown) that transfers the substrate W to the processing unit 2, and a controller 3 that controls the substrate processing apparatus 1.

As shown in FIG. 1, the processing unit 2 includes a spin chuck 4, rotating the substrate W around a vertical rotational axis A1, passing through a central portion of the substrate W, while holding the substrate W horizontally, a shielding plate 11, facing an upper surface of the substrate W held by the spin chuck 4, a facing member 27, facing a lower surface of the substrate W held by the spin chuck 4, and a chamber (not shown), housing the spin chuck 4, the shielding plate 11, and the facing member 27, etc.

The spin chuck 4 includes a disk-shaped spin base 5, held in a horizontal orientation, a plurality of chuck pins 6, projecting upward from an upper surface peripheral edge portion of the spin base 5, and a chuck opening/closing unit 7 that makes the plurality of chuck pins 6 grip the substrate W. The spin chuck 4 further includes a spin shaft 8, extending downward along the rotational axis A1 from a central portion of the spin base 5, and a spin motor 9, rotating the spin shaft 8 to rotate the spin base 5 and the chuck pins 6 around the rotational axis A1. The substrate W is grounded via the chuck pins 6 that are at least partially made from a conductive material. The substrate W may be insulated via the chuck pins 6 that are at least partially made from an insulating material.

The shielding plate 11 is disposed above the spin chuck 4. The shielding plate 11 is supported in a horizontal orientation by a support shaft 12 extending in an up/down direction. The shielding plate 11 has a disk shape with an outer diameter greater than the substrate W. A central axis of the shielding plate 11 is disposed on the rotational axis A1. A lower surface of the shielding plate 11 is parallel to the upper surface of the substrate W and faces the entire upper surface of the substrate W.

The processing unit 2 includes a shielding plate elevating/lowering unit 13, coupled to the shielding plate 11 via the support shaft 12. The processing unit 2 may include a shielding plate rotating unit that rotates the shielding plate 11 around the central line of the shielding plate 11. The shielding plate elevating/lowering unit 13 elevates and lowers the shielding plate 11 between a proximal position (position shown in FIG. 2), at which the lower surface of the shielding plate 11 is close to the upper surface of the substrate W, and a retracted position (position shown in FIG. 1), set above the proximal position.

The processing unit 2 includes a central nozzle 14, discharging processing liquids downward via a central discharge port 11a opening at a lower surface central portion of the shielding plate 11. Discharge ports (discharge ports of a first tube 15 and a second tube 16 to be described below) of the central nozzle 14 that discharge the processing liquids are disposed inside a penetrating hole penetrating through a central portion of the shielding plate 11 in the up/down direction. The discharge ports of the central nozzle 14 are disposed above the central discharge port 11a. The central nozzle 14 is elevated and lowered in the vertical direction together with the shielding plate 11.

FIG. 2 is a sectional view of a vertical section of the facing member 27 included in the processing unit 2.

The central nozzle 14 includes a plurality of inner tubes (the first tube 15 and the second tube 16) that discharge processing liquids downward, and a cylindrical casing 17 that surrounds the plurality of inner tubes. The first tube 15, the second tube 16, and the casing 17 extend in the up/down direction along the rotational axis A1. An inner peripheral surface of the shielding plate 11 surrounds an outer peripheral surface of the casing 17 across an interval in a radial direction (direction orthogonal to the rotational axis A1).

The processing unit 2 includes a chemical liquid piping 18, guiding a chemical liquid to the first tube 15, a chemical liquid valve 19, interposed in the chemical liquid piping 18, and a temperature controller 20 (heater or cooler), adjusting the chemical liquid, supplied from the chemical liquid piping 18 to the first tube 15, to a temperature higher or lower than room temperature (for example, 20 to 30° C.).

The chemical liquid supplied to the first tube 15 as a chemical liquid nozzle is, for example, an etching liquid. The etching liquid may be acidic or may be alkaline. Specific examples of the etching liquid include DHF (diluted hydrofluoric acid), TMAH (tetramethylammonium hydroxide), dNH₄OH (diluted ammonium hydroxide), and SC-1 (mixed liquid containing NH₄OH and H₂O₂). Specific examples of the object that is etched include silicon and silicon oxide film. The etched object may be a TiN (titanium nitride film) film. In this case, a solution containing hydrogen peroxide water is used as the etching liquid. Representative examples of a solution containing hydrogen peroxide water are SC-1 and SC-2 (mixed liquid containing HCl and H₂O₂).

The chemical liquid to be supplied to the first tube 15 may be a liquid other than these. For example, the chemical liquid may be a liquid containing at least one of sulfuric acid, acetic acid, nitric acid, hydrochloric acid, hydrofluoric acid, phosphoric acid, acetic acid, ammonia water, hydrogen peroxide water, organic acid (for example, citric acid, oxalic acid, etc.), organic alkali (for example, TMAH (tetramethylammonium hydroxide), etc.), surfactant, and corrosion inhibitor.

The processing unit 2 includes a rinse liquid pipe 21 that guides rinse liquid to the second tube 16, a rinse liquid valve 22 interposed in the rinse liquid pipe 21. The rinse liquid to be supplied to the second tube 16 serving as a rinse liquid nozzle is pure water (deionized water), for example. The rinse liquid is not limited to pure water, but may be any one of carbonated water, electrolyzed ionic water, hydrogen water, ozone water, and hydrochloric acid water with a dilute concentration (of about 10 to 100 ppm, for example).

The processing unit 2 includes a solvent piping 23, guiding an organic solvent (liquid) to the second tube 16, and a solvent valve 24, interposed in the solvent piping 23. The organic solvent (liquid) supplied to the second tube 16 as a solvent nozzle is, for example, IPA (isopropyl alcohol). The organic solvent is not restricted to IPA and may be another organic solvent, such as HFE (hydrofluoroether), etc.

The processing unit 2 includes a gas piping 25, guiding a gas from a gas supply source to the central discharge port 11a opening at the lower surface central portion of the shielding plate 11, and a gas valve 26, interposed in the gas piping 25. The gas supplied to the central discharge port 11a is, for example, nitrogen gas. The gas is not restricted to nitrogen gas and may be another inert gas, such as helium gas or argon gas, etc., or may be dry air or clean air.

The processing unit 2 includes the facing member 27 that faces the lower surface of the substrate W. The facing member 27 includes a disk-shaped facing portion 29, disposed between the substrate W, held by the spin chuck 4, and the spin base 5, and a supporting portion 28, supporting the facing portion 29. The facing portion 29 includes a disk-shaped dielectric body 30, held in a horizontal orientation, and a plurality of electrodes 31 to 33, disposed inside the dielectric body 30.

The facing portion 29 is held in a horizontal orientation by the supporting portion 28. An outer diameter of the facing portion 29 is smaller than an outer diameter of the substrate W. The plurality of chuck pins 6 are disposed at a periphery of the facing portion 29. The supporting portion 28 extends downward along the rotational axis A1 from a central portion of the facing portion 29. The supporting portion 28 is fixed to a lower surface of the facing portion 29. The facing portion 29 may be integral to the supporting portion 28 or may be a member different from the supporting portion 28.

The supporting portion 28 is inserted in the spin base 5 and the spin shaft 8. The supporting portion 28 is not in contact with the spin base 5 and the spin shaft 8. The supporting portion 28 is fixed so as not to move with respect to the chamber. Therefore, even if the spin chuck 4 rotates, the facing member 27 does not rotate. Therefore, when the spin chuck 4 rotates the substrate W, the substrate W and the facing member 27 rotate relative to each other around the rotational axis A1.

The dielectric body 30 of the facing member 29 is made of insulating material, such as synthetic resin or ceramic, etc. The dielectric body 30 includes a flat, circular upper surface (facing surface 30a), a flat, circular lower surface, and an outer peripheral surface having a diameter smaller than the substrate W. The upper surface of the dielectric body 30 is disposed below the substrate W, held by the plurality of chuck pins 6, so as to face the lower surface of the substrate W in parallel. The lower surface of the dielectric body 30 is disposed above the spin base 5 so as to face an upper surface of the spin base 5 in parallel. The outer peripheral surface of the dielectric body 30 is surrounded by the plurality of chuck pins 6.

The upper surface of the dielectric body 30 is disposed close to the lower surface of the substrate W held by the plurality of chuck pins 6. A distance D4 in the vertical direction from the upper surface of the dielectric body 30 to the lower surface of the substrate W is, for example, less than a thickness D2 of the dielectric body 30. The distance D4 is equal at all positions of the dielectric body 30. Also, an outer diameter of the dielectric body 30 is smaller than the outer diameter of the substrate W. A difference between a radius of the dielectric body 30 and a radius of the substrate W is less than the thickness D2 of the dielectric body 30. Since the difference between the radius of the dielectric body 30 and the radius of the substrate W is small, the upper surface of the dielectric body 30 faces substantially the entire lower surface of the substrate W.

The plurality of electrodes 31 to 33 of the facing portion 29 are made of conductive material, such as metal, etc. The plurality of electrodes 31 to 33 are respectively disposed at a plurality of positions differing in distance in the radial direction from the rotational axis A1. The plurality of electrodes 31 to 33 may be disposed at equal intervals in the radial direction or may be disposed at unequal intervals in the radial direction. The plurality of electrodes 31 to 33 include a first electrode 31, disposed at a radially outer side of the rotational axis A1, a second electrode 32, disposed at a radially outer side of the first electrode 31, and a third electrode 33, disposed at a radially outer side of the second electrode 32.

As shown in FIG. 3, each of the electrodes 31 to 33 has a C-shape fixed in distance from the rotational axis A1 and surrounding the rotational axis A1. The plurality of electrodes 31 to 33 are disposed concentrically. Each of the electrodes 31 to 33 includes, for example, a pair of an anode 34 and a cathode 35. The anode 34 includes a plurality of arcuate portions 34a, surrounding the rotational axis A1, and a collecting portion 34b, connected to each of the plurality of arcuate portions 34a. Similarly, the cathode 35 includes a plurality of arcuate portions 35a, surrounding the rotational axis A1, and a collecting portion 35b, connected to each of the plurality of arcuate portions 35a. The plurality of arcuate portions 34a of the anode 34 and the plurality of arcuate portions 35a of the cathode 35 are aligned alternately in the radial direction. The collecting portion 34b and the collecting portion 35b are disposed closer to a power source than the arcuate portions 34a and the arcuate portions 35a.

As shown in FIG. 2, a distance D1 in the vertical direction from the lower surface of the substrate W held by the plurality of chuck pins 6 to the plurality of electrodes 31 to 33 is less than the thickness D2 (length in the vertical direction) of the dielectric body 30 (distance D1<thickness D2). The dielectric body 30 includes the facing surface 30a that faces the lower surface of the substrate W in parallel. A distance D3 in the vertical direction from the plurality of electrodes 31 to 33 to the facing surface 30a of the dielectric body 30 is less than a distance D4 in the vertical direction from the facing surface 30a of the dielectric body 30 to the lower surface of the substrate W (distance D3<distance D4). The distance D3 may be equal to the distance D4 (distance D3=distance D4) or may be greater than the distance D4 (distance D3>distance D4).

The substrate processing apparatus 1 includes a plurality of (for example, three) power supply devices 37 that apply DC voltages to the plurality of electrodes 31 to 33. The plurality of power supply devices 37 and the plurality of electrodes 31 to 33 are in a one-to-one correspondence. The power supply devices 37 are connected to the corresponding electrodes via wirings 36. A portion of the wirings 36 is disposed inside the facing portion 29 and the supporting portion 28. Each power supply device 37 is connected to a power source (not shown). The voltage of the power source is applied to the plurality of electrodes 31 to 33 via the plurality of power supply devices 37 and the plurality of wirings 36.

Each power supply device 37 includes an on/off portion, performing switching between applying voltage to the corresponding electrode and stopping the voltage application, and a voltage changing portion, changing a magnitude of the voltage applied to the corresponding electrode. The power supply device 37 applies voltages of equal absolute value to the pair of anode 34 and cathode 35. When in a state where the substrate W is disposed above the facing member 27, voltages are applied to the respective electrodes 31 to 33, positive electric charges and negative electric charges gather at the upper surface of the substrate W due to at least one of either of electrostatic induction and electrostatic polarization and the upper surface of the substrate W becomes electrostatically charged.

The magnitude of the voltage applied to an electrode and a voltage application starting time and ending time are determined for each electrode independently by the controller 3. The controller 3 inputs a voltage command value, expressing the magnitude of the voltage to be applied to an electrode, into each power supply device 37. Each power supply device 37 applies the voltage of the magnitude corresponding to the voltage command value to the corresponding electrode.

When voltage command values of the same magnitudes are input from the controller 3 into the respective power supply devices 37, voltages of the same magnitude are applied respectively to the first electrode 31, the second electrode 32, and the third electrode 33. When voltage command values of different magnitudes are input from the controller 3 into the respective power supply devices 37, voltages of different magnitudes are applied to the first electrode 31, the second electrode 32, and the third electrode 33.

As shall be described below, the controller 3 provides commands to the respective power supply devices 37 such that the applied voltages increase in the order of the first electrode 31, the second electrode 32, and the third electrode 33, that is, such that the absolute values of the applied voltages increase in that order. As a specific example of the voltages applied to the respective electrodes 31 to 33, the voltage for the first electrode 31 is ±1 kV, the voltage for the second electrode 32 is ±1.5 kV, and the voltage for the third electrode 31 is ±2 kV.

The broken line of FIG. 7 shows a conceptual image of a distribution of etching amount when the upper surface of the substrate W is etched without electrostatically charging the substrate W. As shown in FIG. 7, the etching amount of the substrate W is greatest at an upper surface central portion of the substrate W and decreases with separation from the upper surface central portion of the substrate W. Although when a liquid landing position of the etching liquid with respect to the upper surface of the substrate W is moved between the central portion and a peripheral edge portion, the uniformity of etching is increased, the etching amount of the substrate W exhibits a hill-shaped distribution in a manner similar to that when the liquid landing position of the etching liquid is fixed at the upper surface central portion of the substrate W.

The present inventors found that when the upper surface of the substrate W is electrostatically charged either positively or negatively, an etching amount per unit time (etching rate) increases. It was further found that the etching rate increases as an electrostatic charge amount (electric charge amount) of the upper surface of the substrate W increases.

The uniformity of etching can thus be increased by electrostatically charging the upper surface of the substrate W such that the electrostatic charge amount increases continuously or stepwise with separation from the upper surface central portion of the substrate W.

The controller 3 is a computer that includes a CPU (Central Processing Device) and a storage device. The controller 3 includes a recipe storage portion 41, storing a plurality of recipes, and a processing executing portion 42 that controls the substrate processing apparatus 1 to make the substrate processing apparatus 1 process the substrate W in accordance with a recipe. The processing executing portion 42 is a functional block realized by the controller 3 executing a program installed in the controller 3.

The recipes are data defining processing contents for the substrate W and include processing conditions and processing procedures for the substrate W. Each recipe further includes a voltage set including the plurality of voltage command values to be applied respectively to the plurality of electrodes 31 to 33. In the present preferred embodiment, a first command value for the first electrode 31, a second command value for the second electrode 32, and a third command value for the third electrode 33 are included in the voltage set. The controller 3 controls the three power supply devices 37 such that the first command value, the second command value, and the third command value are applied to the first electrode 31, the second electrode 32, and the third electrode 33, respectively.

The processing conditions of the substrate W include, for example, at least one among chemical liquid type, chemical liquid concentration, chemical liquid temperature, rotational speed of the substrate during chemical liquid supplying, chemical liquid supplying time, and chemical liquid flow rate. FIG. 5 shows an example where the processing conditions of the substrate W include a chemical liquid type A1, chemical liquid concentrations b1 to b3, chemical liquid temperatures c1 to c3, rotational speeds d1 to d3 of the substrate during chemical liquid supplying, and etching times (chemical liquid supplying times) e1 to e3. The recipes R1 to R3 differ in at least one of the processing conditions. FIG. 5 shows an example where the recipes R1 to R3 differ in chemical liquid concentration, chemical liquid temperature, rotational speed of the substrate during chemical liquid supplying, and etching time.

The voltage sets V1 to V3, included in the respective recipes R1 to R3, are measured values when the uniformity of etching is of a desired value or higher under the processing conditions of the substrate W designated by the corresponding recipe. That is, the respective voltage sets V1 to V3 are measured values obtained when the substrate W is processed with just the voltages applied to the plurality of electrodes 31 to 33 being changed according to processing. Therefore, when the substrate processing apparatus 1 processes the substrate W according to a recipe, the desired uniformity of etching is obtained.

The magnitudes of the voltages applied to the first electrode 31, the second electrode 32, and the third electrode 33 may be the same regardless of the processing conditions of the substrate W. However, when the upper surface of the substrate W is etched without electrostatically charging the substrate W, the etching amount of the substrate W ordinarily exhibits a hill-shaped distribution, such as shown in FIG. 7 regardless of the processing conditions of the substrate W. There are cases where a slope of the hill-shaped curve changes when at least one of the processing conditions differs. It is therefore preferable to change the magnitudes of the voltages in accordance with the processing conditions of the substrate W. In the present preferred embodiment, the voltage set is set according to each processing condition of the substrate W.

FIG. 6 is a flowchart for describing an example of processing of the substrate W executed by the substrate processing apparatus 1. The following respective steps are executed by the controller 3 controlling the substrate processing apparatus 1.

A silicon wafer is an example of the substrate W to be processed. The silicon wafer may be a wafer with a pattern exposed at the surface or may be a wafer with which a front most surface is flat. The pattern may be a line-shaped pattern or a cylindrical pattern. If the pattern is exposed at the front surface that is a device forming surface, the “upper surface (front surface) of the substrate W” includes the upper surface (front surface) of the substrate W (base material) itself and a front surface of the pattern.

When the substrate W is processed by the processing unit 2, a carry-in step of carrying the substrate W into the chamber is performed (step S11 of FIG. 6).

Specifically, in a state where the shielding plate 11 is positioned at the retracted position, the transfer robot (not shown) makes a hand enter the chamber. Thereafter, the substrate W on the hand is placed on the plurality of chuck pins 6 by the transfer robot. Thereafter, the plurality of chuck pins 6 are pressed against the peripheral edge portion of the substrate W and the substrate W is gripped by the plurality of chuck pins 6. After the substrate W is gripped, the spin motor 9 starts rotating the substrate W. After the substrate W is placed on the plurality of chuck pins 6, the transfer robot retracts the hand from an interior of the chamber.

After the substrate W is placed on the plurality of chuck pins 6, the plurality of power supply devices 37 apply voltages of the magnitudes designated in a recipe to the first electrode 31, the second electrode 32, and the third electrode 33 (etching electrostatic charging step). The voltages are thereby applied to the respective electrodes 31 to 33 such that the applied voltages increase in the order of the first electrode 31, the second electrode 32, and the third electrode 33. The substrate W is thus electrostatically charged such that the electrostatic charge amount increases stepwise as an outer peripheral portion of the substrate W is approached. The application of voltages to the respective electrodes 31 to 33 is stopped after discharge of the etching liquid, to be described below, ends.

After the carry-in step is performed, a chemical liquid supplying step (etching step) of supplying the etching liquid, which is an example of the chemical liquid, to the upper surface of the substrate W is performed.

Specifically, the shielding plate elevating/lowering unit 13 lowers the shielding plate 11 from the retracted position to the proximal position. Thereafter, in a state where the shielding plate 11 is positioned at the proximal position, the chemical liquid valve 19 is opened (step S12 of FIG. 6). The etching liquid is thereby discharged from the central nozzle 14 toward the upper surface central portion of the rotating substrate W. When a predetermined time elapses from the opening of the chemical liquid valve 19, the chemical liquid valve 19 is closed and the discharge of the etching liquid from the central nozzle 14 is stopped (step S13 of FIG. 6).

The etching liquid discharged from the central nozzle 14 flows outward along the upper surface of the substrate W. A liquid film of the etching liquid covering the entire upper surface of the substrate W is thereby formed. The lower surface of the shielding plate 11 is disposed higher than the liquid film of the etching liquid and is separated from the liquid film of the etching liquid. The etching liquid that reaches an upper surface peripheral edge portion of the substrate W is expelled to a periphery of the substrate W. The etching liquid is thereby supplied to the entire upper surface of the electrostatically charged substrate W and the upper surface of the substrate W is processed (etched) uniformly.

Next, a rinse liquid supplying step of supplying pure water, which is an example of the rinse liquid, to the upper surface of the substrate W is performed.

Specifically, the rinse liquid valve 22 is opened in the state where the shielding plate 11 is positioned at the proximal position (step S14 of FIG. 6). The pure water is thereby discharged from the central nozzle 14 toward the upper surface central portion of the rotating substrate W. The pure water discharged from the central nozzle 14 flows outward along the upper surface of the substrate W. The pure water that reaches the upper surface peripheral edge portion of the substrate W is expelled to the periphery of the substrate W. The etching liquid on the substrate W is thereby rinsed off by the pure water and the entire upper surface of the substrate W becomes covered by a liquid film of the pure water. When a predetermined time elapses from the opening of the rinse liquid valve 22, the rinse liquid valve 22 is closed and the discharge of pure water from the central nozzle 14 is stopped (step S15 of FIG. 6).

Next, a solvent supplying step of supplying IPA (liquid), which is an example of the organic solvent, to the upper surface of the substrate W is performed.

Specifically, the solvent valve 24 is opened in the state where the shielding plate 11 is positioned at the proximal position (step S16 of FIG. 6). The IPA is thereby discharged from the central nozzle 14 toward the upper surface central portion of the rotating substrate W. The IPA discharged from the central nozzle 14 flows outward along the upper surface of the substrate W. The IPA that reaches the upper surface peripheral edge portion of the substrate W is expelled to the periphery of the substrate W. The pure water on the substrate W is thereby replaced by the IPA and the entire upper surface of the substrate W becomes covered by a liquid film of the IPA. When a predetermined time elapses from the opening of the solvent valve 24, the solvent valve 24 is closed and the discharge of IPA from the central nozzle 14 is stopped (step S17 of FIG. 6).

The plurality of power supply devices 37 apply voltages to the respective electrodes 31 to 33 again after the solvent valve 24 is opened and before the solvent valve 24 is closed (drying electrostatic charging step). The magnitudes of the voltage applied to the respective electrodes 31 to 33 in this step may be equal to or may differ from the magnitudes of the voltage applied to the respective electrodes 31 to 33 in the chemical liquid supplying step. That is, a voltage set for the chemical liquid supplying step and a voltage set for the drying step may be included in the recipe.

In order to electrostatically charge the substrate W uniformly, the plurality of power supply devices 37 may apply, for example, voltages of the same magnitudes to the first electrode 31, the second electrode 32, and the third electrode 33 in the drying electrostatic charging step. Also, voltages may be applied just to the anodes 34 or just to the cathodes 35 of the respective electrodes 31 to 33. The application of voltages to the respective electrodes 31 to 33 is stopped after drying of the substrate W, to be described below, is completed (for example, after the rotation of the substrate W is stopped and before the substrate W is carried out).

After the solvent supplying step has been performed, a drying step of drying the substrate W is performed (step S18 of FIG. 6).

Specifically, the gas valve 26 is opened in the state where the shielding plate 11 is positioned at the proximal position. Nitrogen gas is thereby discharged from the central discharge port 11a of the shielding plate 11 toward the upper surface central portion of the rotating substrate W. Further, the spin motor 9 increases the rotational speed of the substrate W to a high rotational speed (of, for example, several thousand rpm). A large centrifugal force is thereby applied to the IPA attached to the substrate W and the IPA is spun off from the substrate W to its periphery. The IPA is thus removed from the substrate W and the substrate W dries. When a predetermined time elapses from the start of the high speed rotation of the substrate W, the spin motor 9 stops rotating the substrate W and the gas valve 26 is closed.

FIG. 8 shows the manner in which the substrate W, with patterns formed thereon, dries. When the substrate having patterns formed thereon is electrostatically charged, an electrical bias arises in the patterns. Therefore, as shown in FIG. 8, electric charges of the same polarity gather at tips of the respective patterns and the tips of the respective patterns become electrostatically charged with the same or substantially the same amount of electrostatic charge of the same polarity. FIG. 8 shows an example where the tips of the respective patterns are electrostatically charged negatively. A repulsive force (coulombic force) thus acts on two adjacent patterns.

On the other hand, when a liquid surface is present between two adjacent patterns, a surface tension of the liquid acts at boundary positions between the liquid surface and the patterns. That is, an attractive force (surface tension) acts on the two adjacent patterns. However, this attractive force (surface tension) is offset by the repulsive force (coulombic force) due to the electrostatic charging of the substrate W. The substrate W can thus be dried while reducing forces that act on the patterns. Occurrence of pattern collapse can thereby be lessened.

After the drying step has been performed, a carry-out process of carrying the substrate W out from the chamber is performed (step S19 of FIG. 6).

Specifically, the shielding plate elevating/lowering unit 13 elevates the shielding plate 11 from the proximal position to the retracted position. Thereafter, the plurality of chuck pins 6 separate from the peripheral end surface of the substrate W to release the gripping of the substrate W. Thereafter, in the state where the shielding plate 11 is positioned at the retracted position, the transfer robot makes the hand enter the interior of the chamber. Thereafter, the transfer robot takes the substrate W on the spin chuck 4 by the hand and retracts the hand from the interior of the chamber.

As described above, with the first preferred embodiment, the substrate W is electrostatically charged by applying voltages to the plurality of electrodes 31 to 33. Then, while making the substrate W rotate around the central rotational axis A1, passing through the central portion of the substrate W, in the state where the substrate W is electrostatically charged, the etching liquid is supplied to the upper surface of the substrate W. The upper surface of the substrate W is thereby etched.

A distance in the radial direction (direction orthogonal to the rotational axis A1) from the rotational axis A1 of the substrate W to the first electrode 31 is less than a distance in the radial direction from the rotational axis A1 of the substrate W to the second electrode 32. The distance in the radial direction from the rotational axis A1 of the substrate W to the second electrode 32 is less than a distance in the radial direction from the rotational axis A1 of the substrate W to the third electrode 33. That is, the second electrode 32 faces the substrate W at a position further outward than the first electrode 31, and the third electrode 33 faces the substrate W at a position further outward than the second electrode 32.

The absolute value of the voltage applied to the second electrode 32 is greater than the absolute value of the voltage applied to the first electrode 31. The absolute value of the voltage applied to the third electrode 33 is greater than the absolute value of the voltage applied to the second electrode 32. The upper surface of the substrate W is thus electrostatically charged such that the electrostatic charge amount increases stepwise with separation from the upper surface central portion of the substrate W. The uniformity of etching can thus be increased in comparison to a case where the upper surface of the substrate W is etched in a state where the substrate W is electrostatically charged uniformly.

Also, in the first preferred embodiment, liquid is removed from the substrate W in the state where the substrate W is charged. The substrate W is thereby dried. As mentioned above, the attractive force (surface tension) that acts on two adjacent patterns is offset by the repulsive force (coulombic force) due to the electrostatic charging of the substrate W. The substrate W can thus be dried while reducing forces that act on the patterns. The occurrence of pattern collapse can thereby be lessened.

Also, with the first preferred embodiment, the plurality of electrodes 31 to 33 face the substrate W via the dielectric body 30. Due to the dielectric body 30, made of insulating material, being present between the substrate W and the plurality of electrodes 31 to 33, electric charges do not or are unlikely to move between the substrate W and the plurality of electrodes 31 to 33 via the dielectric body 30. The substrate W can thus be reliably maintained in the electrostatically charged state and the electrostatic charge amount of the substrate W can be stabilized. The uniformity of etching can thereby be increased more reliably.

Also, with the first preferred embodiment, the plurality of electrodes 31 to 33 are disposed close to the substrate W such that the distance D1 from the substrate W to the plurality of electrodes 31 to 33 is less than the thickness D2 of the dielectric body 30. If the distance D1 from the substrate W to the plurality of electrodes 31 to 33 is large, high voltages must be applied to the plurality of electrodes 31 to 33 to electrostatically charge the substrate W. Therefore, by disposing the plurality of electrodes 31 to 33 close to the substrate W, the substrate W can be electrostatically charged reliably while suppressing the absolute values of the applied voltages.

### Second Preferred Embodiment

A second preferred embodiment of the present invention shall now be described. In regard to FIG. 9 and FIG. 10 below, components equivalent to respective portions shown in FIG. 1 to FIG. 8 shall be provided with the same reference numerals as in FIG. 1, etc., and description thereof shall be omitted.

In the second preferred embodiment, the facing member 27 according to the first preferred embodiment is omitted, and in place of the shielding plate 11 according to the first preferred embodiment, a shielding plate 211, corresponding to a facing member according to the second preferred embodiment, is provided.

The shielding plate 211 includes a disk-shaped facing portion 29 held in a horizontal orientation. The facing portion 29 has a disk shape with an outer diameter smaller than the outer diameter of the substrate W. A central axis of the facing portion 29 is disposed on the rotational axis A1. The facing portion 29 is disposed above the substrate W. As a facing surface 30a, a lower surface of the facing portion 29 is parallel to the upper surface of the substrate W and faces substantially the entire upper surface of the substrate W. A lower end portion of the central nozzle 14 is disposed inside a penetrating hole penetrating through a central portion of the facing portion 29 in the up/down direction.

The shielding plate 211 is coupled to the shielding plate elevating/lowering unit 13 (see FIG. 1) via the support shaft 12. Although the shielding plate 211 is capable of being elevated and lowered in the vertical direction between a proximal position and a retracted position, it is incapable of rotating around the central line of the shielding plate 211 (rotational axis A1). Also, in the second preferred embodiment, the outer diameter of the shielding plate 211 is smaller than the outer diameter of the substrate W and therefore even if the shielding plate 211 is brought close to the substrate W, the shielding plate 211 and the chuck pins 6 do not come in contact with each other. The lower surface of the shielding plate 211 can thus be brought closer to the upper surface of the substrate W.

The shielding plate 211 includes a plurality of electrodes 231 to 233 disposed inside a dielectric body 30. The plurality of electrodes 231 to 233 are respectively disposed at a plurality of positions differing in distance in the radial direction from the central line of the shielding plate 211 (rotational axis A1). The plurality of electrodes 231 to 233 may be disposed at equal intervals in the radial direction or may be disposed at unequal intervals in the radial direction.

The plurality of electrodes 231 to 233 include a first electrode 231, disposed at a radially outer side of the rotational axis A1, a second electrode 232, disposed at a radially outer side of the first electrode 231, and a third electrode 233, disposed at a radially outer side of the second electrode 232. Each of the electrodes 231 to 233 has an O-shape fixed in distance from the rotational axis A1 and surrounding the rotational axis A1. The plurality of electrodes 231 to 233 are disposed concentrically.

The plurality of electrodes 231 to 233 are connected to the plurality of power supply devices 37 via the plurality of wirings 36. Each power supply device 37 includes the on/off portion, performing switching between applying voltage to the corresponding electrode and stopping the voltage application, and the voltage changing portion, changing the magnitude of the voltage applied to the corresponding electrode. The voltage changing portion is capable of changing the voltage, applied to the corresponding electrode, in a range extending from negative to positive (for example, a range from −10 kV to 10 kV). The magnitude of the voltage applied to an electrode and the voltage application starting time and ending time are determined for each electrode independently by the controller 3.

The controller 3 may apply voltages of equal absolute value and polarity to the respective electrodes 231 to 233 or may apply voltages differing from the voltage applied to another electrode in at least one of polarity or absolute value to the remaining electrodes. As an example of combination of voltages applied to the respective electrodes 231 to 233, the voltage applied to the first electrode 231 is +1 kV, the voltage applied to the second electrode 232 is +5 kV, and the voltage applied to the third electrode 233 is +10 kV. As another example of combination of voltages applied to the respective electrodes 231 to 233, the voltage applied to the first electrode 231 is −10 kV, the voltage applied to the second electrode 232 is −10 kV, and the voltage applied to the third electrode 233 is −10 kV.

As in the first preferred embodiment, the controller 3 controls the substrate processing apparatus 1 to make the substrate processing apparatus 1 execute the respective steps from the carry-in step to the carry-out steps. As shown in FIG. 9, in the chemical liquid supplying step (etching step), the controller 3 makes the substrate W be electrostatically charged such that the electrostatic charge amount increases stepwise from the rotational axis A1 to the outer peripheral portion of the substrate W. FIG. 9 shows an example where the upper surface of the substrate W is electrostatically charged negatively.

The controller 3 may bring the lower surface of the shielding plate 211 into contact with the liquid film on the substrate W in at least one step among the chemical liquid supplying step, the rinse liquid supplying step, and the solvent supplying step. That is, in the second preferred embodiment, an outer periphery of the shielding plate 211 is disposed further inward than the chuck pins 6 and therefore the lower surface of the shielding plate 211 can be brought closer to the upper surface of the substrate W. The controller 3 may thus perform a liquid sealing processing of filling an interval between the shielding plate 211 and the substrate W with liquid. The respective electrodes 231 to 233 face the upper surface of the substrate W via the dielectric body 30 made of insulating material. Therefore, even if the interval between the shielding plate 211 and the substrate W is filled with the chemical liquid in the chemical liquid supplying step, electric charges do not move between the respective electrodes 231 to 233 and the substrate Wand the electrostatically charged state of the substrate W is maintained.

Also, the controller 3 may change the polarities of the voltages applied to the respective electrodes 231 to 233 in accordance with the type of processing liquid designated in a recipe. When an alkaline liquid is supplied to the upper surface of the substrate W, particles in the liquid become electrostatically charged negatively. When an acidic liquid is supplied to the upper surface of the substrate W, particles in the liquid become electrostatically charged positively, depending on the pH. If, when an alkaline liquid is supplied to the upper surface of the substrate W, the upper surface of the substrate W is electrostatically charged negatively, electrical repulsive forces act between the particles and the upper surface of the substrate W. Similarly, if, when an acidic liquid is supplied to the upper surface of the substrate W, the upper surface of the substrate W is electrostatically charged positively, electrical repulsive forces act between the particles and the upper surface of the substrate W, depending on the pH of the liquid.

With the second preferred embodiment, when positive voltages are applied to the respective electrodes 231 to 233, negative electric charges gather at the upper surface of the substrate W, and when negative voltages are applied to the respective electrodes 231 to 233, positive electric charges gather at the upper surface of the substrate W. If the chemical liquid designated in a recipe is alkaline, the controller 3 may apply positive voltages to the respective electrodes 231 to 233 to make the upper surface of the substrate W become electrostatically charged negatively. Similarly, if the chemical liquid designated in a recipe is acidic, the controller 3 may apply negative voltages to the respective electrodes 231 to 233 to make the upper surface of the substrate W become electrostatically charged positively. Specifically, the voltage command value includes the magnitude of voltage and the polarity (plus or minus) of voltage, and the polarity of the voltage command value may be set in advance according to the type of chemical liquid.

Also, with the second preferred embodiment, the plurality of electrodes 231 to 233 are disposed above the substrate W. When the substrate W is held by the spin chuck 4 in a state where the front surface is faced upward, the plurality of electrodes 231 to 233 are disposed at the front surface side of the substrate W and face the tips of the patterns formed on the front surface of the substrate W. Distances from the plurality of electrodes 231 to 233 to the tips of the patterns can thus be reduced in comparison to a case where the plurality of electrodes 231 to 233 are disposed below the substrate W. The occurrence of pattern collapse during drying of the substrate W can thus be lessened.

### Other Preferred Embodiments

Although the preferred embodiments of the present invention have been described above, the present invention is not restricted to the contents of the above-described preferred embodiments and various modifications are possible within the scope of the present invention.

For example, although, with the processing example of the substrate W in each of the preferred embodiments described above, a case where the application of voltages to the plurality of electrodes is stopped temporarily was described, the voltage application may be sustained from before the start of supplying of the chemical liquid to the end of drying of the substrate W. Also, voltages may be applied to the plurality of electrodes just when the chemical liquid is supplied to the substrate W or just when the substrate W is being dried. That is, one of either of the etching electrostatic charging step and the drying electrostatic charging step may be omitted.

Further, it may be considered that the temperature of the chemical liquid actually supplied to the substrate W differs from the temperatures specified in the recipes R1 to R3. In this case, the substrate processing apparatus 1 may be arranged as follows.

That is, the controller 3 acquires an actual measured temperature of the chemical liquid from a temperature sensor measuring the temperature of the chemical liquid actually supplied to the substrate W. The controller 3 then calculates the differences between the actual measured temperature of the chemical liquid and the temperatures c1 to c3 (set temperatures) set in the recipes R1 to R3 used at that time. The controller 3 corrects the voltage sets V1 to V3 specified in the recipes R1 to R3 based on the difference temperatures, for example, as follows.

FIG. 11 is a graph of correlation of chemical liquid temperature and etching rate. FIG. 12 is a graph of correlation of applied voltage and etching rate. The controller 3 refers to the correlation of chemical liquid temperature and etching rate (FIG. 11) and the correlation of applied voltage and etching rate (FIG. 12) to correct the voltage sets V1 to V3.

As shown in FIG. 11, there exists a correlation, indicated by Formula 1, between the temperature (x) of NH₄OH, which is an example of a chemical liquid, and the etching rate (y) of amorphous silicon (a-Si).

y=0.2706x+0.8188 Formula 1:

The controller 3 can determine an approximate value of a variation amount of the etching rate due to the difference temperatures by applying the differences between the chemical liquid temperatures c1 to c3 specified in the recipes R1 to R3 and the actual measured temperature of the chemical liquid to Formula 1. For example, according to Formula 1, it is predicted that when the temperature (x) of the chemical liquid actually supplied to the substrate W is 1° C. higher than a set temperature, the etching rate (y) increases by 0.2706.

The controller 3 changes the voltage sets V1 to V3 so that such a variation of the etching rate is compensated. The voltage sets V1 to V3 are changed by referencing the correlation of applied voltage and etching rate (FIG. 12).

As shown in FIG. 12, there exists a correlation, indicated by Formula 2, between the applied voltage (x) and the etching rate (y).

y=0.2778x+1 Formula 2:

The controller 3 applies the etching rate (y), determined by Formula 1, to Formula 2 to determine an approximate value of the applied voltage that compensates the variation of the etching rate. The voltage sets V1 to V3, specified in the recipes R1 to R3, are then corrected by just the calculated applied voltage. For example, when the chemical liquid temperatures c1 to c3, specified in the recipes R1 to R3, are 1° C. lower than the actual measured chemical liquid temperature, it is predicted by Formula 1 that the etching rate will be decreased by 0.2706. The compensation value (x) of the applied voltage is determined by substituting 0.2706 in (y) of Formula 2. In this case, the controller 3 increases the voltage sets V1 to V3, specified in the recipes R1 to R3, by just the determined value. The actual etching rate can thereby be made to match the desired etching rate.

The controller 3 can thus refer to Formula 1 and Formula 2 to correct the values of the voltage sets V1 to V3, specified in the recipes, such that the desired etching rate is obtained even when the liquid temperatures specified in the recipes differ from the actual measured chemical liquid temperature. The etching rate can thereby be controlled precisely.

Although, with the processing example of the substrate W in each of the preferred embodiments described above, a case of performing the solvent supplying step of supplying IPA (liquid), which is an example of an organic solvent, to the upper surface of the substrate W was described, the solvent supplying step may be omitted.

Although, with each of the preferred embodiments described above, a case where the liquid landing positions of the processing liquids (the chemical liquid, the rinse liquid, and the organic solvent) with respect to the upper surface of the substrate W are kept fixed at the central portion was described, the liquid landing positions of the processing liquids with respect to the upper surface of the substrate W may instead be moved between the central portion and the peripheral edge portion. Specifically, the processing unit 2 may include a processing liquid nozzle, discharging the processing liquids toward the upper surface of the substrate W, and a nozzle moving unit, moving the processing liquid nozzle horizontally.

In the second preferred embodiment, the spin chuck 4 may be a vacuum chuck that suctions a lower surface (rear surface) of the substrate W on an upper surface of a suction base that is held in a horizontal orientation.

Two or more of all components described above may be combined. Two or more of all steps described above may be combined.

The present invention corresponds to Japanese Patent Application No. 2015-064945 filed on Mar. 26, 2015 in the Japan Patent Office, and the entire disclosure of this application is incorporated herein by reference.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

### DESCRIPTION OF THE REFERENCE NUMERALS

1: Substrate processing apparatus
2: Processing unit
3: Controller
4: Spin chuck (substrate holding unit)
14: Central nozzle (etching liquid supplying unit)
15: First tube (etching liquid supplying unit)
16: Second tube
18: Chemical liquid piping (etching liquid supplying unit)
19: Chemical liquid valve (etching liquid supplying unit)
20: Temperature controller
21: Rinse liquid piping
22: Rinse liquid valve
23: Solvent piping
24: Solvent valve
27: Facing member
28: Supporting portion
29: Facing portion
30: Dielectric body
30a: Facing surface
31: First electrode
32: Second electrode
33: Third electrode
34: Anode
35: Cathode
36: Wiring
37: Power supply device
41: Recipe storage portion
42: Processing executing portion
211: Shielding plate (facing member)
231: First electrode
232: Second electrode
233: Third electrode
A1: Rotational axis
D1: Distance
D2: Thickness
D3: Distance
D4: Distance
W: Substrate

1. A substrate processing apparatus comprising:
a substrate holding unit, rotating a substrate around a rotational axis passing through a central portion of the substrate while holding the substrate;
an etching liquid supplying unit, supplying an etching liquid to a major surface of the substrate held by the substrate holding unit;
a plurality of electrodes, including a first electrode, facing the substrate held by the substrate holding unit, and a second electrode, disposed at a position more distant than that of the first electrode from the rotational axis and facing the substrate held by the substrate holding unit; and
a controller, controlling the substrate holding unit, the etching liquid supplying unit, and the plurality of electrodes; and
wherein the controller executes
an etching step of supplying the etching liquid to the major surface of the substrate while rotating the substrate around the rotational axis, and
an etching electrostatic charging step of applying voltages to the plurality of electrodes such that absolute values of the applied voltages increase in the order of the first electrode and the second electrode to electrostatically charge the major surface of the substrate in parallel to the etching step.

2. The substrate processing apparatus according to claim 1, wherein the etching electrostatic charging step is a step of applying voltages to the plurality of electrodes such that the major surface of the substrate becomes electrostatically charged positively when the etching liquid is acidic and applying voltages to the plurality of electrodes such that the major surface of the substrate becomes electrostatically charged negatively when the etching liquid is alkaline.

3. The substrate processing apparatus according to claim 1, wherein the substrate is a substrate at the major surface of which a pattern is exposed, and
the controller further executes
a drying step of removing liquid from the substrate to dry the substrate after the etching step and
a drying electrostatic charging step of applying voltages to the plurality of electrodes to electrostatically charge the major surface of the substrate in parallel to the drying step.

4. The substrate processing apparatus according to claim 3, wherein the plurality of electrodes face the major surface of the substrate.

5. The substrate processing apparatus according to claim 1, further comprising: a dielectric body, in which the plurality of electrodes are embedded and which is interposed between the substrate held by the substrate holding unit and the plurality of electrodes.

6. The substrate processing apparatus according to claim 5, wherein a distance from the substrate, held by the substrate holding unit, to the plurality of electrodes is less than a thickness of the dielectric body.

7. A substrate processing method comprising:
an etching step of supplying an etching liquid to a major surface of a substrate while rotating the substrate around a rotational axis passing through a central portion of the substrate; and
an etching electrostatic charging step of electrostatically charging the major surface of the substrate in parallel to the etching step such that an electrostatic charge amount increases as a distance from a central portion of the major surface of the substrate increases.

8. The substrate processing method according to claim 7, wherein the etching electrostatic charging step is a step of electrostatically charging the major surface of the substrate positively if the etching liquid is acidic and electrostatically charging the major surface of the substrate negatively if the etching liquid is alkaline.

9. The substrate processing apparatus according to claim 7, wherein the substrate is a substrate at the major surface of which a pattern is exposed, and
the substrate processing method further comprises:
a drying step of removing liquid from the substrate to dry the substrate after the etching step; and
a drying electrostatic charging step of electrostatically charging the major surface of the substrate in parallel to the drying step.
